(19) United States
(12) Patent Application Publication
(10) Pub. No.: US 2005/0248037 A1
(43) Pub. Date: Nov. 10, 2005

(54) Flip-chip package substrate with a high-density layout

(75) Inventors: Chih-Pin Hung, Kaohsiung (TW); Pao-Nan Li, Pingtung (TW); Hsueh-Te Wang, Kaohsiung (TW); Yun-Hsiang Tien, Kaohsiung (TW)

Correspondence Address: BACON & THOMAS, PLLC, 625 SLATERS LANE, FOURTH FLOOR, ALEXANDRIA, VA, 22314, US

(73) Assignee: Advanced Semiconductor Engineering, Inc., Kaohsiung (TW)

(21) Appl. No.: 11/123,204

(22) Filed: May 6, 2005

(30) Foreign Application Priority Data
May 6, 2004 (TW) 93112734

(51) Int. Cl. H01L 21/48; H01L 23/52

(52) U.S. Cl. 257/778; 438/108; 257/786

(57) ABSTRACT

A flip-chip package substrate with a high-density layout. A number of pads and a number of traces are formed on an upper surface of the substrate. At least a pad has a short axis and a vertical long axis which are perpendicular to each other. The distance between the elongated pad and the pad adjacent thereto is not smaller than two thirds of the length of the short axis, so that at least two of the traces can pass between the elongated pad and the pad adjacent thereto.

### BACKGROUND OF THE INVENTION

1. Field of the Invention

The invention relates in general to a flip-chip package substrate, and more particularly to a flip-chip package substrate with a high-density layout.

2. Description of the Related Art

Along with the requirements of slimness, light weight, compactness and high speed, flip-chip package has become the mainstream in semiconductor package. The layout design of the flip-chip package substrate is crucial in meeting the requirements of flip-chip package. The IC chip carrier disclosed in Taiwanese Patent Publication No. 549582 is an example of a flip-chip package substrate according to the prior art. The IC chip carrier includes a substrate, a patterned conducting wire layer and a patterned solder mask. The substrate has an upper surface on which the conducting wire layer and the solder mask are disposed. The conducting wire layer has a number of pads and a number of traces. The pads correspond to a lump on a flip chip and are disposed in the flip-chip region of the upper surface of the substrate. Each pad has a long axis and a corresponding short axis. The length of any of the long axes is larger than the length of the corresponding short axis. An angle is included between two adjacent long axes with the range of the included angle being 0o˜10o. The included angle between one of the long axes and the corresponding short axis is 80o˜100o. The solder mask covers the traces of the conducting wire layer. The solder mask has a number of openings exposing the corresponding pads. Circular pads go with long openings, long pads go with circular openings, or long pads go with long openings, so that the matching tolerance of the openings of the solder mask of the IC chip carrier, a flip-chip package substrate for instance, can be increased. However, the pads are aligned with such a high density that the pitch between the centers of the pads can be as small as below micrometers. After deducting the length of the short axes of the pads, that is, the diameter of a circular pad, the clearance between two adjacent pads only allows one single trace to pass through. The pads disposed in inner rows, being unable to be fanned out via the traces disposed on the upper surface the substrate, need to be electrically conducted to a lower surface of the substrate. Therefore, a large number of through holes need to be disposed in the flip-chip region, which is on the upper surface of the substrate, for the pads disposed in inner rows to be fanned out via an additional circuit layer disposed on the inner surface, not only incurring extra costs to the manufacturing of the substrate but also reducing the space usage of the upper surface of the substrate. Furthermore, the grounding layer and power source layer on the inner surface of the substrate are also affected.

Refer to FIGS. 1 and 2. A flip-chip region 12 is disposed on an upper surface 11 of a conventional flip-chip package substrate 10. A number of pads 20 are formed on the flip-chip region 12 in matrix with high-density. The pads 20 of the substrate 10 are fanned out by being connected to ends of the traces 30, and then are electrically conducted to the lower surface of the substrate 10 via the through holes 40 and the circuit layer on the inner surface of the substrate 10 to be bonded with solder ball or solder paste. A solder mask 50 is further disposed on the upper surface 11 of the substrate 10 to protect the traces 30. The solder mask 50 has a number of openings 51 corresponding to the pads 20 to expose the pads 20. The diameter of the circular openings 51 is allowed to range from 85 to 90 micrometers (μm). With the advance in the micro-pitch of the substrate pad 20, when the pitch P between two centers of two adjacent pads 20 on the substrate 10 is requested to be not larger than 200 micrometers (P=D+φ, wherein D denotes the distance between the pads, φ denotes the diameter of the pad). In order to comply with the design tolerance of ±20% for the openings 51 of the solder mask 50, the conventional design of the openings 51 is circular or oval-shaped. If the diameter of the opening 51 of the solder mask 50 is 90 micrometers, the pads 20 need to reserve an outer peripheral for 15 to 25 micrometers. Therefore, the diameter φ of each pad 20 is approximately 130 micrometers with the distance D between the two adjacent pads 20 being equal to 70 micrometers only. According to the current technology with regard to the design of the substrate, only one trace 30 whose width W equaling 20 micrometers can pass through the clearance between the two adjacent pads 20. When the pitch of the two adjacent pads 20 is not larger than 200 micrometers, the edge distance D of two adjacent pads 20 cannot be designed for two or more than two traces to pass through, no matter the circular pad is matched with a long opening, the long pad is matched with a circular opening, or the long pad is matched with a long opening. A certain number of through holes 40 are designed to be in the flip-chip region 12 of the substrate 10, therefore, the layout design and the number of circuit layers of the substrate 10 are restricted.

### SUMMARY OF THE INVENTION

It is therefore an object of the invention to provide a flip-chip package substrate with a high density layout, which improves the flexibility of the trace layout and the function of the high-density layout and keeps the consistency of electricity and heat-effect of the flip-chip package substrate.

The invention achieves the above-identified object by providing a flip-chip package substrate with a high density layout. A flip-chip region is disposed on an upper surface of the substrate. The substrate includes a number of pads and a number of traces. The traces are disposed in the flip-chip region. At least one of the pads has a short axis and a long axis which are perpendicular to each other, so that the distance between the elongated pad and the pad adjacent thereto is not smaller than two thirds of the length of the short axis, and that at least two of the traces pass through the clearance between the elongated pad and the pad adjacent thereto. Therefore, the flexibility of the trace layout and the function of the high-density layout are improved.

The invention achieves the above-identified object by providing another flip-chip package substrate with a high-density layout. The substrate includes a number of pads and a number of traces. The pads and the traces are disposed on an upper surface of the substrate. When the pitch between two adjacent pads is not larger than 200 micrometers, the edge distance between the adjacent pads is over 80 micrometers. The adjacent pads are non-circular and elongated, and the exposed area of each pad is not smaller than 6000 squared micrometers (μm²), so that the electricity and heat-effect of the flip-chip package substrate remain consistent.

The invention achieves the above-identified object by further providing a flip-chip package substrate with a high-density layout. The substrate includes a number of pads, a number of through holes and a number of traces connecting the pads and the through holes. The upper surface of the substrate includes a flip-chip region and a peripheral region. A number of pads are aligned in matrix in the flip-chip region. Under the circumstances of having the same exposed area and the same pitch, at least a pad has a short axis and a long axis which are perpendicular to each other, so that the distance between the elongated pad and the pad adjacent thereto is not smaller than two thirds of the length of the short axis for at least two trace pass through the clearance between the elongated pad and the pad adjacent thereto, and that the through holes can be fanned out and aligned on the edge of the substrate to improve the high-density layout design of the substrate.

Other objects, features, and advantages of the invention will become apparent from the following detailed description of the preferred but non-limiting embodiments. The following description is made with reference to the accompanying drawings.

### BRIEF DESCRIPTION OF THE DRAWINGS

FIG. 1 (Prior Art) is a top view of a conventional substrate;

FIG. 2 (Prior Art) is a partial enlarged view of a conventional substrate;

FIG. 3 is a top view of a flip-chip package substrate with a high-density layout according to a preferred embodiment of the invention;

FIG. 4 a partial enlarged view of a flip-chip package substrate with a high-density layout according to a preferred embodiment of the invention; and

FIG. 5 is a cross-sectional view of a flip-chip package substrate with a high-density layout according to a preferred embodiment of the invention.

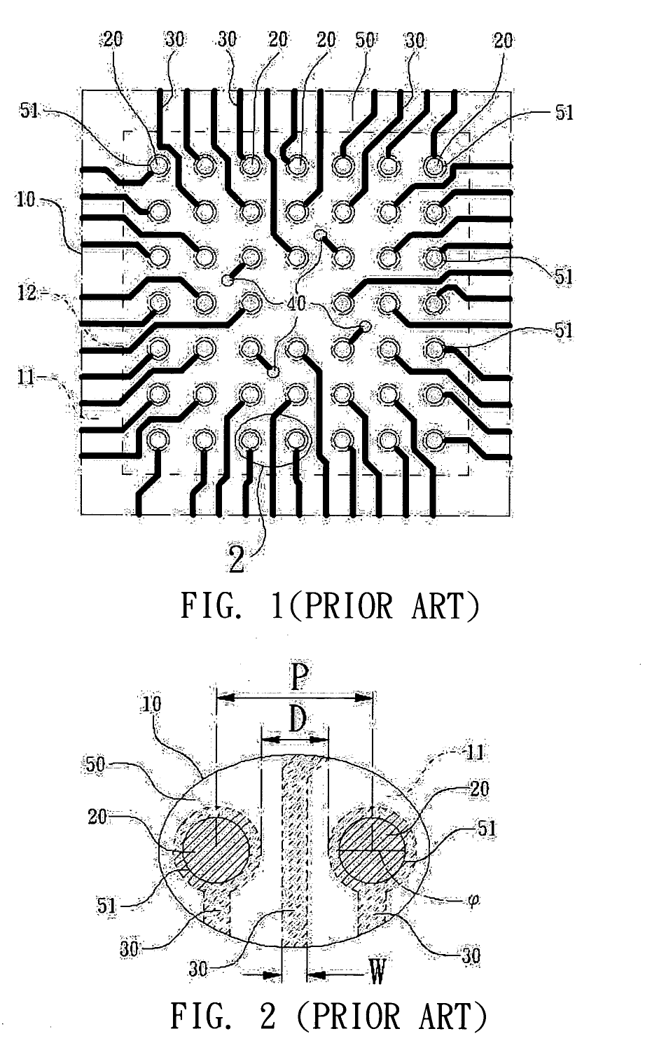

### DETAILED DESCRIPTION OF THE INVENTION

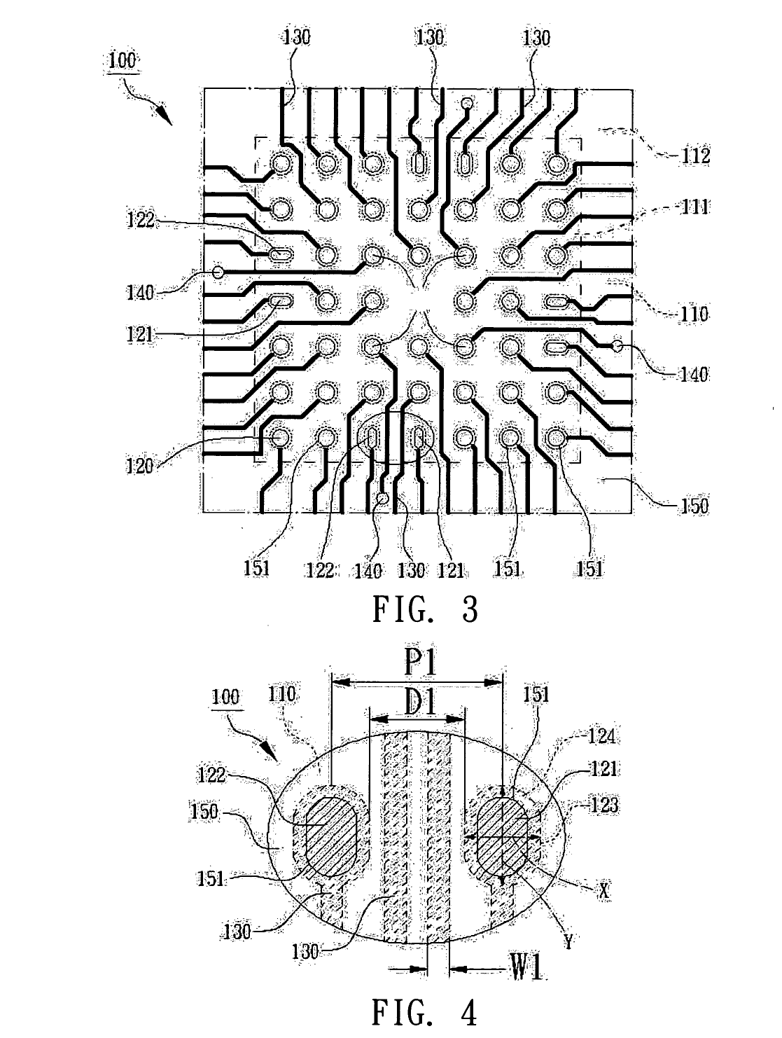

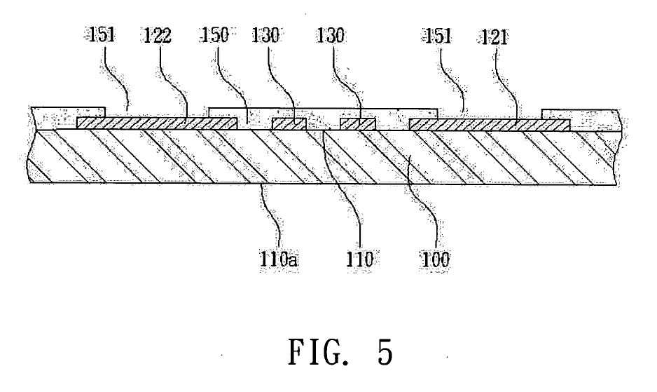

Referring to FIGS. 3, 4 and 5, a flip-chip package substrate 100 with a high-density layout according to a preferred embodiment of the invention is exemplified. The flip-chip package substrate 100 has an upper surface 110 and a corresponding lower surface 110a. The upper surface 110 is for a flip chip (not shown in the diagram) to be bonded on, the lower surface 110a is a bonding surface of the flip-chip package as shown in FIG. 5. The substrate 100 is a build-up substrate of high-density layout and is preferably made of Bismaleimide Triazine (BT) resin. The substrate 100 can have a number of through holes 140 and a number of metal layers (not shown in the diagram), such as a grounding layer, a power source layer or a signal transmission layer, disposed within for the upper surface 10 and the lower surface 110a of the substrate 100 to be electrically conducted. Referring to FIG. 3, the upper surface 110 of the substrate 100 includes a flip-chip region 111 and a peripheral region 112. The substrate 100 includes a number of pads 120, a number of traces 130 and a number of through holes 140.

Refer to FIGS. 3 and 4. The pads 120, which are aligned in matrix and are formed in the flip-chip region 111 of the substrate 100, can be made of metals such as copper or aluminum. The exposed surface of the pads 120 can be electroplated with nickel, gold or an alloy of other metals. In order to effectively bond a number of lumps on a flip chip (not shown in the diagram), the pads 120 have the same exposed area and the same pitch. According to the preferred embodiment, the exposed area of the pads 120 is exemplified to be not smaller than 6000 squared micrometers (μm²), while the pitch P1 of the pads 120 is exemplified to be not larger than 200 micrometers (μm). The pitch P1 refers to the distance between the centers of the two adjacent pads 120. The pads 120 at least include a first pad 121 and a second pad 122 adjacent thereto. The first pad 121 is elongated and has a short axis X and a long axis Y that are perpendicular to each other with the length of the short axis X being smaller than the length of the long axis Y. Preferably, the second pad 122 is also elongated and has a short axis X and a long axis Y that are perpendicular to each other. According to the preferred embodiment, the length of the short axis X is smaller than 120 micrometers and preferably ranges from 110 to 120 micrometers, so that the edge distance D1 between the first pad 121 and the second pad 122 can be not smaller than two thirds of the length of the short axis X of the first pad 121. According to the preferred embodiment, the edge distance D1 is not smaller than 80 micrometers, so that the clearance of the edge distance D1 between the first pad 121 and the second pad 122 adjacent thereto can be widened for at least two traces 130 to pass through so as to achieve the high-density layout with the micro-pitch between the two pads. Refer to FIG. 4. In the preferred embodiment, both of the first pad 121 and the second pad 122 have two straight sides 123 parallel to the long axis and two curved sides 124 connecting two ends of the two straight sides. Each curved side 124 forms a U shape with two straight sided 123 to assure that the pads 120 have the same exposed area for flip-chip bonding.

Refer to FIG. 3 again. The through holes 140 are disposed on the upper surface 110 of the substrate 100 for a lump on the flip-chip (not shown in the diagram) to be electrically conducted to the inner surface or the lower surface 110a of the substrate 100. Furthermore, the traces 130 formed on the upper surface 110 of the substrate 100 connect the pads 120 and the corresponding through holes 140, and the elongated first pad 121 enables the distance D1 between the first pad 121 and the second pad 122 to be not smaller than two thirds of the length of the short axis X of the first pad 121 or the second pad 122. In the preferred embodiment, since the length of the short axis X can be reduced to be 110 micrometers under the same exposure area, the edge distances D1 are 90 micrometers when the pitch between the first pad 121 and the second pad 122 is fixed at 200 micrometers. In terms of the current manufacturing technology of the substrate, the clearance between two adjacent pads is wide enough for two conducting traces 130 whose width W1 ranges from 15 to 25 micrometers to pass through. The edge distance in the segment where the two conducting traces 130 pass through the clearance between the first pad 121 and the second pad 122 adjacent thereto is not larger than 20 micrometers, so that most of the traces 130 can be fanned out to the peripheral region 112 of the substrate 100 from the flip-chip region 111. Therefore, most through holes 140 can effectively fan out the peripheral region 112 disposed on the substrate 100 to improve the high-density layout design of the substrate 100.

Refer to FIGS. 3 and 5. A solder mask 150 is formed on the upper surface 110 of the substrate 100 to cover the traces 130. The solder mask 150 has a number of openings 151, which are smaller than the corresponding pads 120, first pads 121 and second pads 122 thereof to define the exposed area of the pads 120, 121, 122. That is, the pads 120 are solder mask define (SMD) pads. The openings 151 corresponding to the first pads 121 and the second pads 122 are elongated and become non-circular, so that the exposed area of pads 120, the first pad 121 and the second pad 122 is fixed to be the same. Due to the tolerance in the design of the openings 151 of the solder mask 150, the edge distances between the openings 151 and the corresponding pads 120, the first pad 121 and the second pad 122 range from 15 to 25 micrometers, and the exposed length of the short axis X of the first pad 121 in the solder mask opening 151 is not smaller than 75 micrometers. According to the preferred embodiment, the pitch of the pads 120 is fixed at a pre-determined value (200 micrometers), so the exposed area of the pads 120, 121, and 122 in the solder mask opening 151 is preferably not smaller than 6000 squared micrometers (μm²). However, the exposed area of the pads 120, 121, and 122 can also be fixed at other sizes according to the specifications of flip-chip.

The first pad 121 is elongated and has a long axis Y and a short axis X which are perpendicular to each other. Furthermore, the curved side in the two ends of the long axis Y forms a capsular shape with the straight side in the two ends of the short axis X, so that the distance between the elongated first pad 121 and the second pad 122 adjacent thereto is not smaller than two thirds of the length of the short axis X, and that a number of traces 130 pass through the clearance between the elongated first pad 121 and second pad 122 adjacent thereto. Therefore, the flexibility in trace layout design and the function of high-density layout can be improved. The through holes 140 can be disposed on the peripheral 113 of the substrate 100 to reduce the through holes that would otherwise be disposed on the inner surface and increase the space usage of the flip-chip package substrate 100. When the pitch P1 of the pads 120 is not larger than 200 micrometers, the exposed area of each pad 120 is not smaller than 6000 squared micrometers, so the electricity and heat-effect of the flip-chip package substrate 100 can remain consistent without reducing the exposure area of the pads 120. Besides, the edge distance between the openings 141 of the solder mask 150 and the corresponding pads 130 ranges from 15 to 25 micrometers and still complies with a tolerance of ±20% in the design of the openings 141 of the solder mask 150. To achieve a unity shape of the pads, the pads 120 can be designed to have the same shape with the first pad 121 and the second pad 122 and have the same exposed area and the same pitch P1.

The invention is not limited to be applied in the solder mask define (SMD) pad of the substrate flip-chip region. The invention can also be applied in the substrate whose solder mask is larger than a number of openings of the pads to completely expose the pads. The pads are non-solder mask define (NSMD) pad, which use at least an elongated pad. The elongated pad has a short axis and a long axis. The distance between the elongated pad and the pad adjacent thereto is not smaller than two thirds of the length of the short axis, so that at least two traces can pass through the clearance between two adjacent pads and most through holes are fanned outside the flip-chip region of the substrate.

While the invention has been described by way of example and in terms of a preferred embodiment, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

1. A flip-chip package substrate, comprising:
an upper surface having a flip chip region;
a first pad and a second pad adjacent thereto, formed in the flip-chip region, wherein the first pad has a short axis and a long axis, so that an edge distance between the first pad and the second pad is not smaller than two thirds of a length of the short axis of the first pad; and
a plurality of traces formed on the upper surface of the substrate, wherein at least two traces pass between the first pad and the second pad.

2. The flip-chip package substrate according to claim 1, wherein the traces are extended to a periphery of the upper surface from the flip-chip region.

3. The flip-chip package substrate according to claim 1, further comprising a plurality of through holes, wherein the traces are connected to the through holes.

4. The flip-chip package substrate according to claim 3, wherein the through holes are disposed on the upper surface of the substrate other than the flip-chip region.

5. The flip-chip package substrate according to claim 1, wherein the first pad has two straight sides parallel to the long axis and two curved sides connecting two ends of the two straight sides, and each curved side forms a U shape with the two straight sides.

6. The flip-chip package substrate according to claim 1, wherein the length of the short axis of the first pad ranges from 110 to 120 micrometers.

7. The flip-chip package substrate according to claim 1, wherein the edge distance between the first pad and the second pad is not smaller than 80 micrometers.

8. The flip-chip package substrate according to claim 1, wherein an edge distance in a segment where the traces passing through a clearance between the first pad and the second pad adjacent thereto is not larger than 20 micrometers.

9. The flip-chip package substrate according to claim 1, further comprising a solder mask formed on the upper surface of the substrate to cover the traces.

10. The flip-chip package substrate according to claim 9, wherein the solder mask has a plurality of non-circular openings to define an exposed area of the pads.

11. The flip-chip package substrate according to claim 10, wherein the length of the short axis exposed in the openings is not smaller than 75 micrometers.

12. The flip-chip package substrate according to claim 10, wherein edge distances between the openings of the solder mask and the corresponding pads range from 15 to 25 micrometers.

13. A flip-chip package substrate, comprising:
an upper surface having a flip chip region and a peripheral region, wherein the peripheral region has a plurality of through holes disposed thereon;
a plurality of pads formed in the flip-chip region of the substrate in matrix, wherein the pads have identical exposed area and identical pitches, and wherein at least one pad has a short axis and a long axis, so that the distance between the one pad and another pad adjacent thereto is smaller than two thirds of a length of the short axis of the one pad; and
a plurality of traces formed on the upper surface of the substrate, for connecting the corresponding pads and the through holes, wherein at least two traces pass between the one pad and the another pad adjacent thereto.

14. The flip-chip package substrate according to claim 13, wherein the one pad has two straight sides parallel to the long axis and two curved sides connecting two ends of the two straight sides, and each curved side forms a U shape with the two straight sides.

15. The flip-chip package substrate according to claim 13, further comprising a solder mask formed on the upper surface of the substrate to cover the traces.

16. The flip-chip package substrate according to claim 15, wherein the solder mask has a plurality of openings to define the exposed area of the pads, so that the pads are solder mask define (SMD) pads.

17. The flip-chip package substrate according to claim 15, wherein the solder mask has a plurality of openings being larger than the corresponding pads to completely expose the pads, so that the pads are non-solder mask define (NSMD) pads.

18. The flip-chip package substrate f according to claim 15, wherein the solder mask has a plurality of openings, the edge distances between the openings and the corresponding pads are fixed and range from 15 to 25 micrometers.
